(19) United States
(12) Patent Application Publication
(10) Pub. No.: US 2026/0050030 A1
(43) Pub. Date: Feb. 19, 2026

(54) TEST INTERPOSER MODULAR STRUCTURE

(71) Applicants: Po-Jung Yeh, Taoyuan City (TW); Cheng-Jung Chien, Taoyuan City (TW)

(72) Inventors: Po-Jung Yeh, Taoyuan City (TW); Cheng-Jung Chien, Taoyuan City (TW)

(21) Appl. No.: 18/806,725

(22) Filed: Aug. 16, 2024

(51) Int. Cl. G01R 31/28; G01R 1/073

(52) U.S. Cl. CPC G01R 31/2889; G01R 1/07314; G01R 31/2887

(57) ABSTRACT

The present invention provides a test interposer modular structure applied in a test packaging machine, which includes an upper mold and a lower mold. An interposer is disposed between the upper mold and the lower mold and has an upper top surface recessed toward a lower bottom surface thereof to form a concave portion with a blocking portion on the periphery of the concave portion. When conducting a test, as the upper mold and the lower mold approach each other, the solder balls of an electronic circuit device located between the interposer and the upper mold enter the concave portion, while the portions of the electronic circuit device without the solder balls abut against the blocking portion. This can distribute pressure, preventing internal cracks at the contact points of the solder balls and the interposer, thereby maintaining stability during electrical testing.

### BACKGROUND OF THE INVENTION

### Fields of the Invention

The present invention relates to a test interposer modular structure, specifically applied in the field of circuit boards and wafers and primarily used for protecting circuit boards and wafers to ensure the integrity between the DRAM and solder balls or between solder balls and the interposer during the test and to maintain stability during the test.

### Description of Related Art

High-precision devices such as circuit boards and wafers rely heavily on the connections between various electronic components. Taking circuit boards as an example, a circuit board is primarily composed of copper clad laminates (CCL), prepreg (PP sheets), copper foil, solder mask, and silkscreen layer. After installing the electronic components onto the circuit board, they must be soldered using solder, forming conductive loops through the metallic properties of the copper foil.

As shown in FIGS. 13 and 14, the so-called Package on Package (POP) is an advanced packaging technology that integrates multiple chip components and usually used in space-constrained applications such as mobile phone CPUs. It allows multiple wafers 4 and circuit boards to be stacked together, saving space and improving performance. In the testing of POP packaging, the most important consideration is whether the electronic components are correctly soldered, such as for testing the soldering between the circuit boards and the wafers 4 of units under test. However, contact cannot be repeated for the solder balls 6, once they have made contact with the electronic components through soldering. Thus, the circuit board and wafer 4 must be frequently replaced, leading to increased testing costs. Furthermore, to meet the requirement of increasing the speed of the circuit boards and the wafer 4 to 10800 mbps, the thickness of the interposer 5 needs to be reduced to 0.8 mm or less. According to past experiences, reducing the thickness of the interposer 5 can lead to pressure concentration on the solder balls 6 of the circuit board and the wafer 4 during testing. This can cause internal cracks between the circuit board/the wafer 4 and the solder balls 6, or between the solder balls 6 and the interposer 5, resulting in unstable testing and increased costs.

### SUMMARY OF THE INVENTION

The primary objective of the invention is to prevent internal cracking between solder balls at solder points and the circuit board/wafer, as well as between the solder balls and an interposer, during testing for POP packaging of circuit boards and wafers. This maintains the electrical connection between the aforementioned components to ensure stability during testing, thus addressing deficiencies of conventional technology.

To achieve the aforementioned effects and address the deficiencies of conventional technology, the present invention primarily provides two main embodiments. The first embodiment involves a test interposer modular structure applied in a test packaging machine, which includes an upper mold and a lower mold. It provides an interposer between the upper mold and the lower mold. The interposer includes an upper top surface, a lower bottom surface and four side surfaces. Additionally, the upper top surface is recessed toward the lower bottom surface to form a concave portion with a blocking portion on the periphery of the concave portion. When conducting a test, as the upper mold and the lower mold approach each other, a plurality of solder balls of an electronic circuit device located between the interposer and the upper mold enter the concave portion, while the portions of the electronic circuit device without the solder balls abut against the blocking portion. This prevents direct pressure on the solder balls, avoiding cracks.

The second embodiment of the present invention provides another test interposer modular structure applied in a test packaging machine, which includes an upper mold and a lower mold. It provides an interposer between the upper mold and the lower mold and a supporting board stacked on the interposer. The supporting board has a plurality of through-holes extending from an upper surface to a lower surface. When conducting a test, as the upper mold and the lower mold approach each other, a plurality of solder balls of an electronic circuit device located between the supporting board and the upper mold enter the corresponding through-holes, while the portions of the electronic circuit device without the solder balls abut against the upper surface of the supporting board. This prevents direct pressure on the solder balls, avoiding cracks.

For the two main technical features described above, the common advantage is that during testing the POP packaging of electronic circuit devices (circuit boards, wafers), the recessed feature of the concave portion or the supporting board can prevent direct contact between the solder balls of the electronic circuit device (circuit board, wafer) and the interposer. This avoids internal cracks at the solder joints between the electronic circuit device (circuit board, wafer) and the solder balls, maintaining stability during electrical testing. The same issue between the solder balls and the interposer is also addressed by using the supporting board to avoid cracking in the solder balls caused by pressure during contact with the interposer when the electronic circuit device makes contact with the interposer. The pressure from the electrical contact between the solder balls of the electronic circuit device and the interposer can be distributed across the supporting board, preventing internal cracks in the solder balls at the contact points with the interposer.

### BRIEF DESCRIPTION OF THE DRAWINGS

FIG. 1 is a schematic view of the planar mechanism of the interposer in accordance with the first embodiment of the present invention, the test packaging machine and the electronic circuit device when they are not yet close to each other.

FIG. 2 is an exploded perspective schematic view of the interposer in accordance with the first embodiment of the present invention and the electronic circuit device.

FIG. 2A is another perspective schematic view of FIG. 2 from a different angle.

FIG. 3 is a perspective schematic view of the operation of stacking the interposer in accordance with the first embodiment of the present invention and the electronic circuit device.

FIG. 4 is a cross-sectional schematic view taken along the IV-IV line of FIG. 3.

FIG. 5 is a schematic view of the planar mechanism of the interposer in accordance with the second embodiment of the present invention, the test packaging machine and the electronic circuit device when they are not yet close to each other.

FIG. 6 is an exploded perspective schematic view of the interposer in accordance with the second embodiment of the present invention and the electronic circuit device.

FIG. 7 is a perspective schematic view of the operation of stacking the interposer in accordance with the second embodiment of the present invention and the electronic circuit device.

FIG. 8 is a cross-sectional schematic view taken along the VIII-VIII line of FIG. 7.

FIG. 9 is a schematic view of the planar mechanism of the supporting board in accordance with the third embodiment of the present invention, the test packaging machine and the electronic circuit device when they are not yet close to each other.

FIG. 10 is an exploded perspective schematic view of the supporting board in accordance with the third embodiment of the present invention, the electronic circuit device and the interposer.

FIG. 11 is a perspective schematic view of the operation of stacking the supporting board in accordance with the third embodiment of the present invention, the electronic circuit device and the interposer.

FIG. 12 is a cross-sectional schematic view taken along the XII-XII line of FIG. 11.

FIG. 13 is a schematic view of the planar structure of a conventional POP packaging machine being used to conduct a multiple chip packaging test.

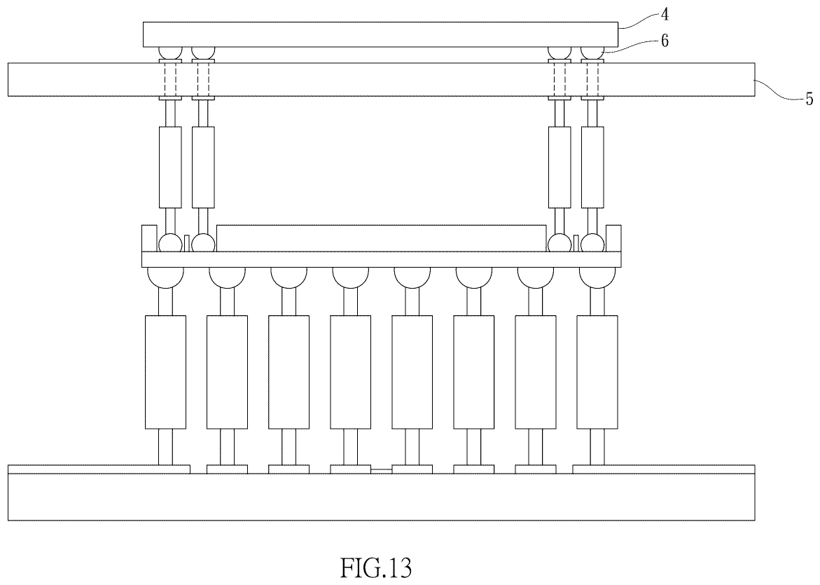

FIG. 14 is a planar schematic view for illustrating cracks between solder balls of the chip and the interposer in the conventional POP packaging machine.

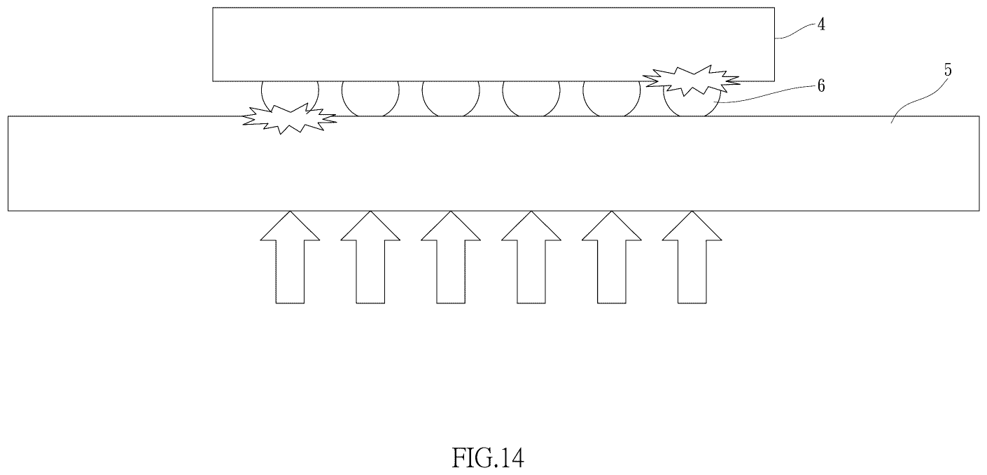

### DETAILED DESCRIPTION OF THE PREFERRED EMBODIMENT

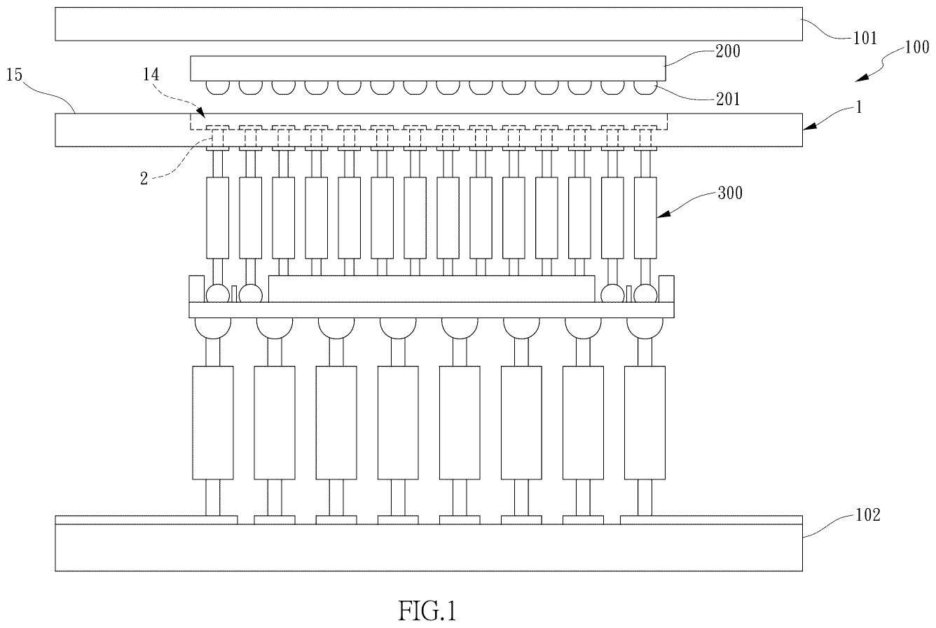

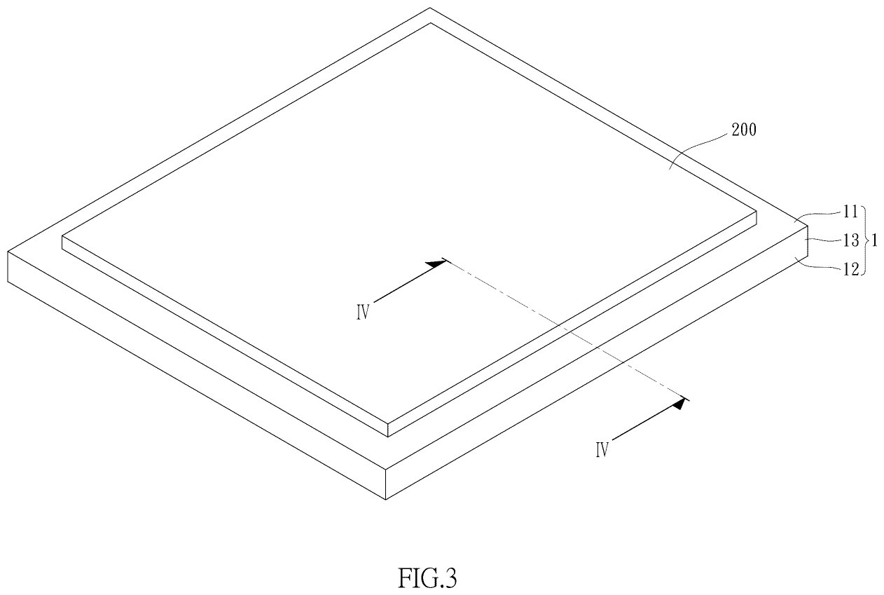

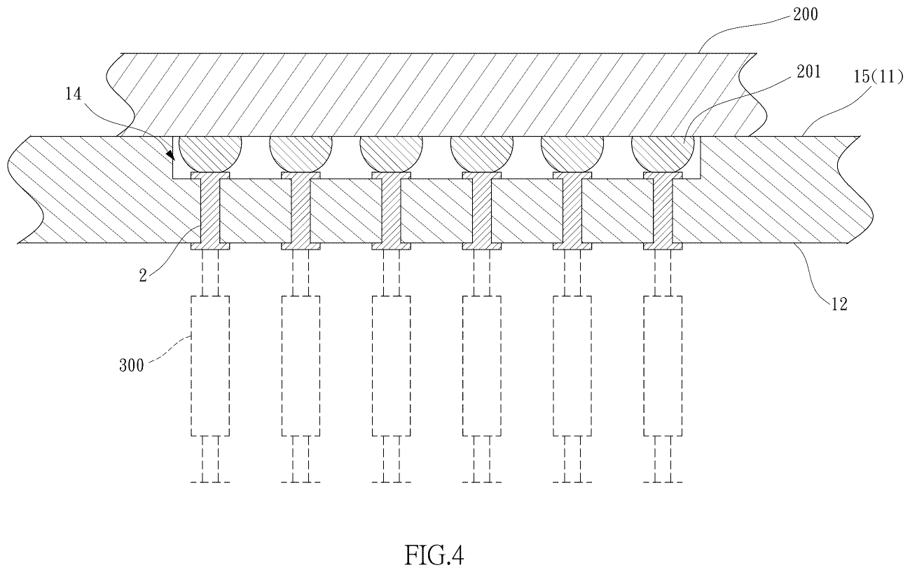

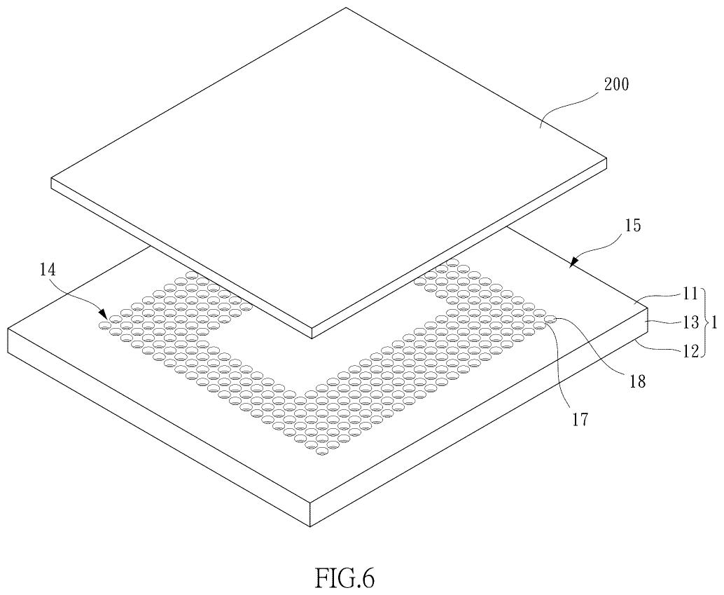

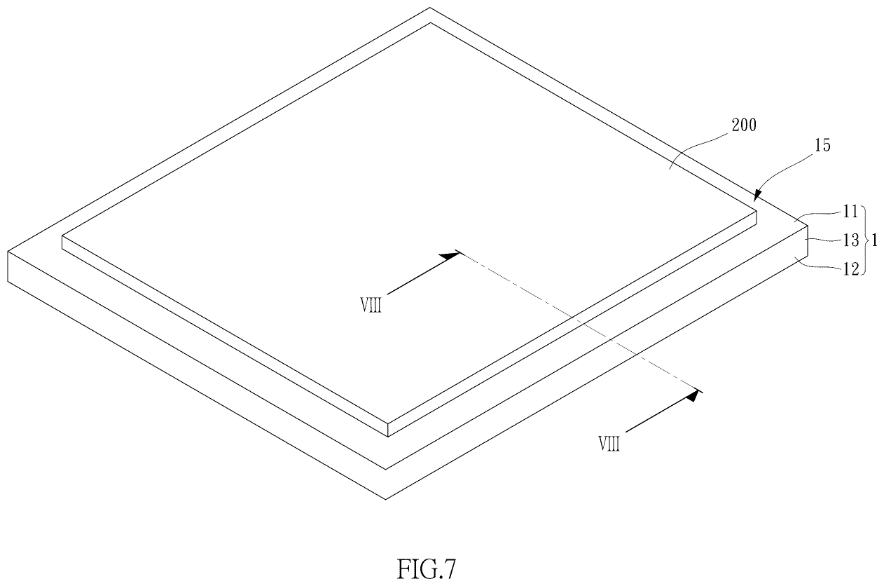

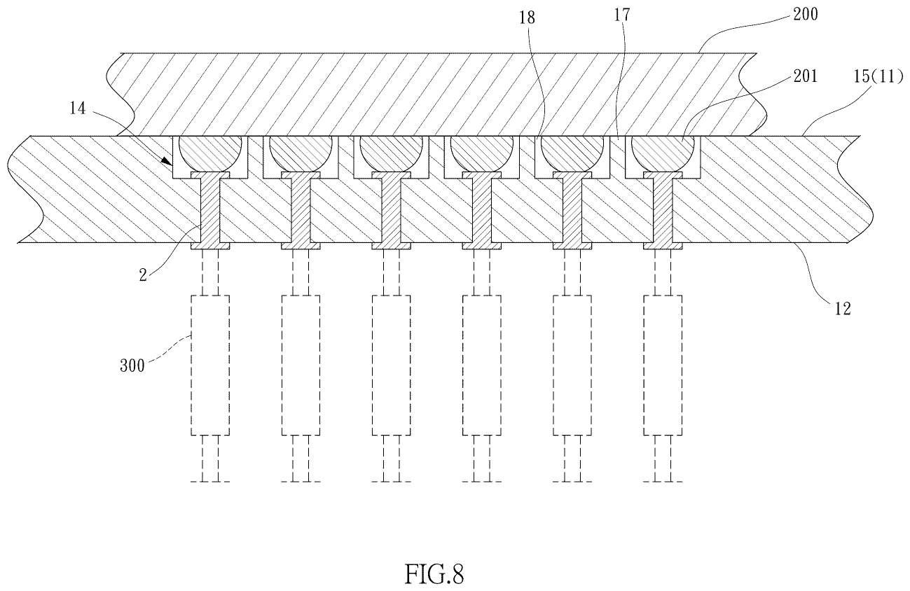

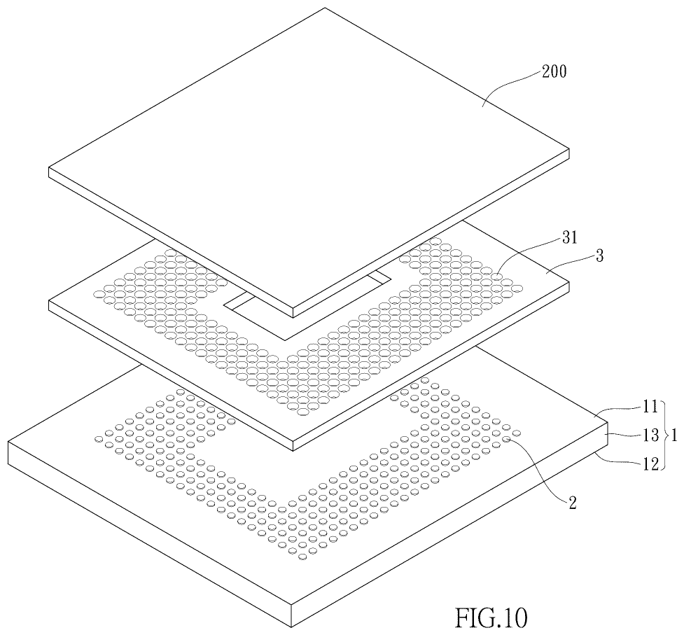

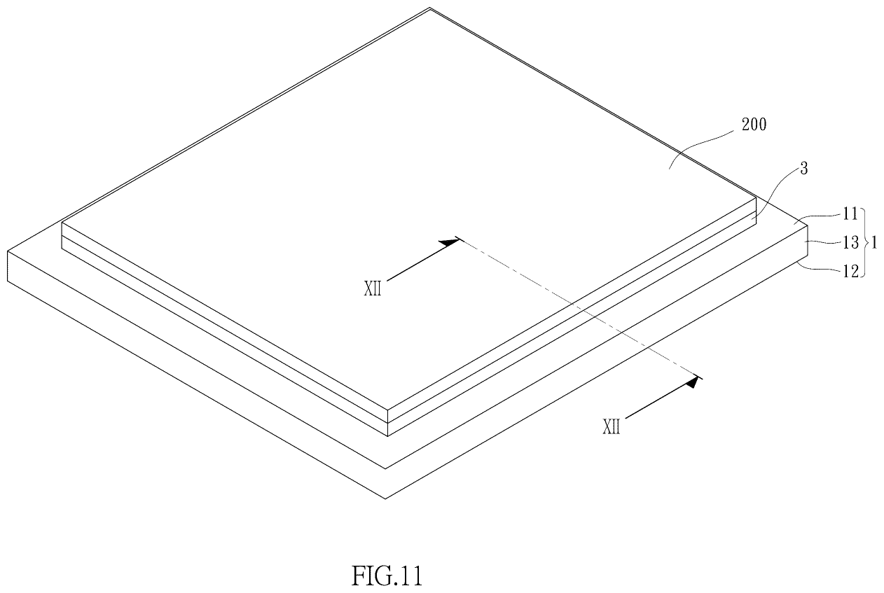

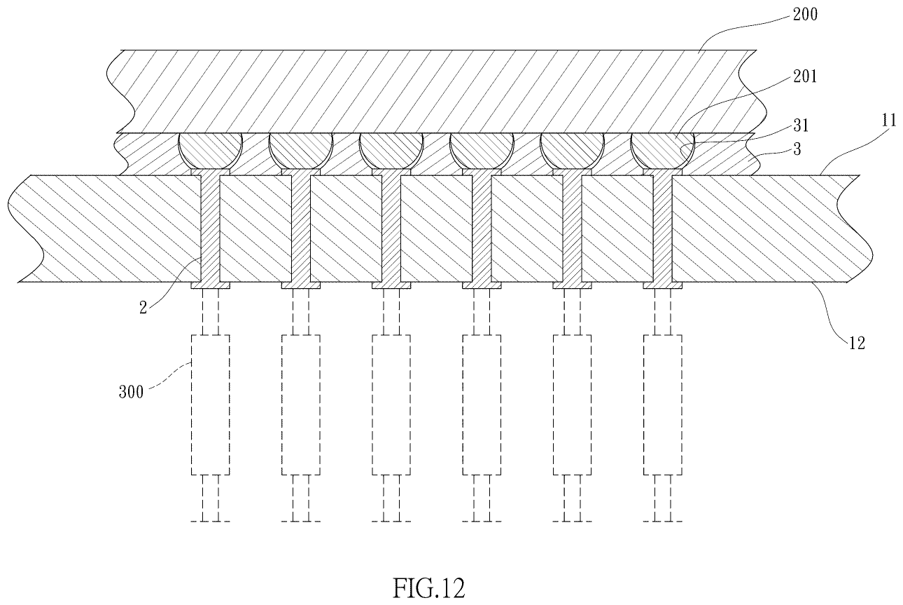

As shown in FIGS. 1 to 12, the present invention provides a test interposer modular structure, applied within a test packaging machine 100. The test packaging machine 100 is mainly used for electrically testing wafers and circuit boards to check the conductivity between electronic components within the wafers and the circuit boards. The test packaging machine 100 includes an upper mold 101 and a lower mold 102. The testing method involves placing a wafer or circuit board (both referred as electronic circuit device 200 for illustration) within the test packaging machine 100. Upon activation, the upper mold 101 and the lower mold 102 gradually approach each other. The interposer 1, located between the upper mold 101 and the lower mold 102, includes an upper top surface 11, a lower bottom surface 12, and four side surfaces 13. The interposer 1 is a rectangular plate, and the upper top surface 11 is recessed towards the lower bottom surface 12 to form a concave portion 14 and a blocking portion 15 located on the periphery of the concave portion 14. When conducting a test, as the upper mold 101 and the lower mold 102 approach each other, a plurality of solder balls 201 of the electronic circuit device 200 located between the interposer 1 and the upper mold 101 enter the concave portion 14. In the electronic circuit device 200, the pins of the electronic components are soldered with solder that forms spherical bodies, known as solder balls, around the pins. And, the portions of the electronic circuit device 200 without the plurality of solder balls 201 abut against the blocking portion 15 to prevent the solder balls 201 from being directly pressed and cracking.

According to the above description of the present invention, when a user conducts a test on the electronic circuit device 200, the upper mold 101 and the lower mold 102 will be equipped with testing instruments capable of making electrical contact (known as Pogo Pins), which are testing tools mainly used for IC testing. They have elastic properties and can provide stable contact force and connection, ensuring the accuracy and reliability of the test. The elasticity allows them to connect closely to the IC pins during testing and maintain consistent performance over multiple tests, thus improving production efficiency and test accuracy. Therefore, when the electronic circuit device 200 is placed within the test packaging machine 100, by engaging the upper mold 101 and the lower mold 102, the numerous probes built in the upper mold 101 and the lower mold 102 will make direct or indirect electrical contact with the solder balls 201 of the electronic circuit device 200, allowing for conductivity testing. However, in conventional scenarios, during dynamic testing, the repeated contact of the pogo pins with the interposer 5 causes pressure to concentrate on the solder balls 6 of the wafer 4 or the circuit board. This causes internal cracks between the wafer 4/circuit board and the solder balls 6 or between the solder balls 6 and the interposer 5, resulting in unstable testing. The present invention addresses this issue by forming the concave portion 14 on the side of the interposer 1 corresponding to the electronic circuit device 200. This allows the portions of the electronic circuit device 200 with the solder balls 201 to enter the concave portion 14, while the portions without the solder balls 201 abut against the blocking portion 15. This prevents the solder balls 201 from being subjected to pressure and cracking, provides additional support and stability, reduces the stress on the solder balls 201, and thereby extends the lifespan of the electronic circuit device 200 while lowering replacement costs.

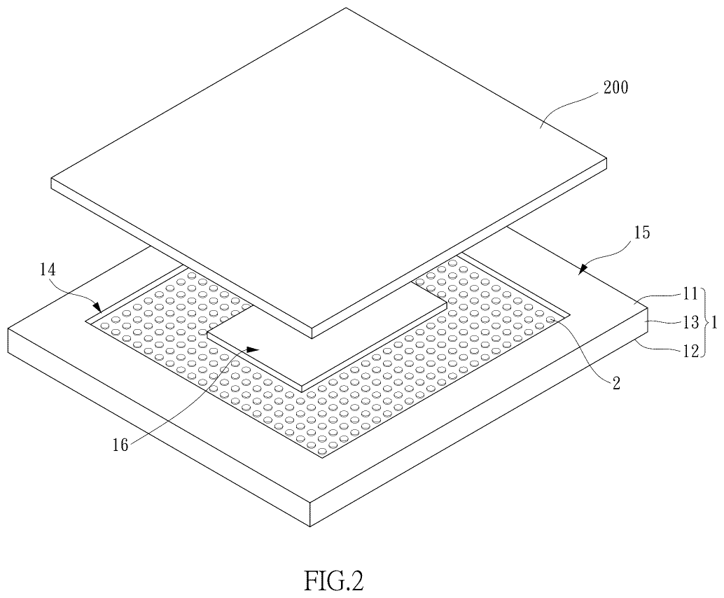

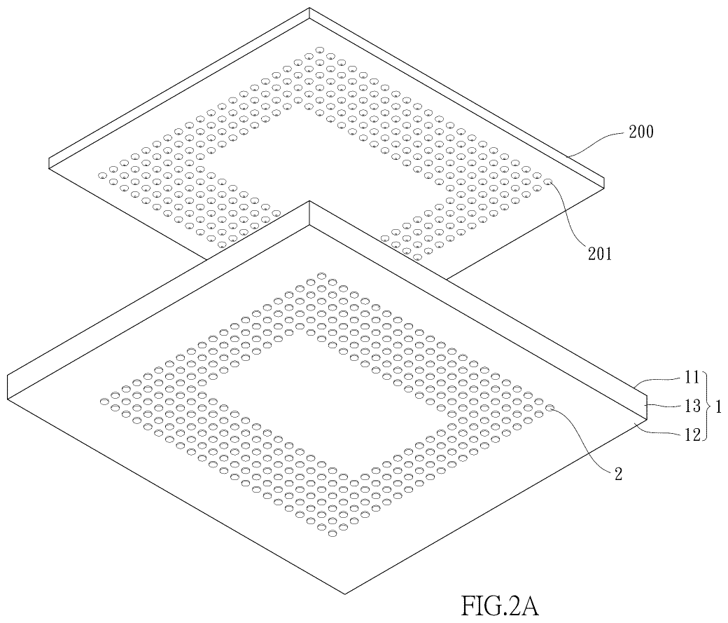

Furthermore, following the above description, additional technical features and structures of the present invention are described below. Firstly, various embodiments are provided to illustrate the design of the concave portion 14 of the interposer 1. In the common type of electronic circuit device 200, as shown in FIG. 2A, the portions with the solder balls 201 are in a square shape, and the portions without the solder balls 201 are located at the center and periphery. Therefore, two embodiments for the interposer 1 are provided to match the type of electronic circuit device 200. In the first embodiment, as shown in FIGS. 1 to 4, the concave portion 14 of the interposer 1 is formed as a groove recessed from the upper top surface 11 towards the lower bottom surface 12. A plurality of conductive elements 2 are embedded between the concave portion 14 and the lower bottom surface 12. During testing operations with the test packaging machine 100, as the upper mold 101 and lower mold 102 come together, the interposer 1 gradually approaches a plurality of test probes 300, enabling the conductive elements 2 to make electrical contact with the test probes 300. Also, the electronic circuit device 200 gradually approaches the interposer 1, and the solder balls 201 enter the concave portion 14 and make electrical contact with the conductive elements 2. The portions of the electronic circuit device 200 without the solder balls 201 abut against the blocking portion 15 (corresponding to the periphery of the electronic circuit device 200) of the interposer 1. This prevents the solder balls 201 from bearing excessive pressure and cracking.

Continuing from the previous description, in addition to the configuration primarily relying on the blocking portion 15 around the concave portion 14 of the interposer 1 to support the electronic circuit device 200, a supporting portion 16 can be formed to protrude from the concave portion 14, corresponding to the central portion (without the plurality of solder balls 201) of the electronic circuit device. The supporting portion 16 mainly assists the blocking portion 15 in supporting the electronic circuit device 200, thereby reducing the pressure on the electronic circuit device 200 when the upper mold 101 and the lower mold 102 come together, as shown in FIGS. 2 and 2A.

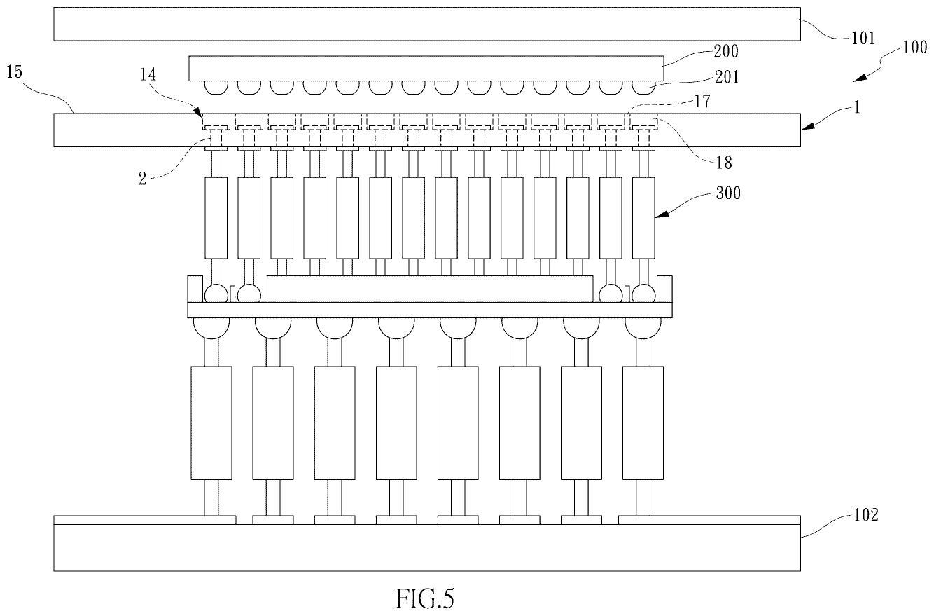

In the second embodiment of the present invention (as shown in FIGS. 5 to 8), unlike the first embodiment where a single recessed space corresponds to all solder balls 201, the single recessed space is partitioned to correspond individually to each solder ball 201 in the second embodiment. Thus, the interior of the groove of the concave portion 14 further includes a plurality of partitions 17 arranged in a grid pattern to form a plurality of compartments 18 corresponding to each solder ball position. Each of the compartments 18 is a spherical space matching the shape of the solder ball 201. In the second embodiment, the arrangement of the partitions 17 can increase the support for the electronic circuit device 200 and further distribute the pressure to avoid excessive concentration on the solder balls 201.

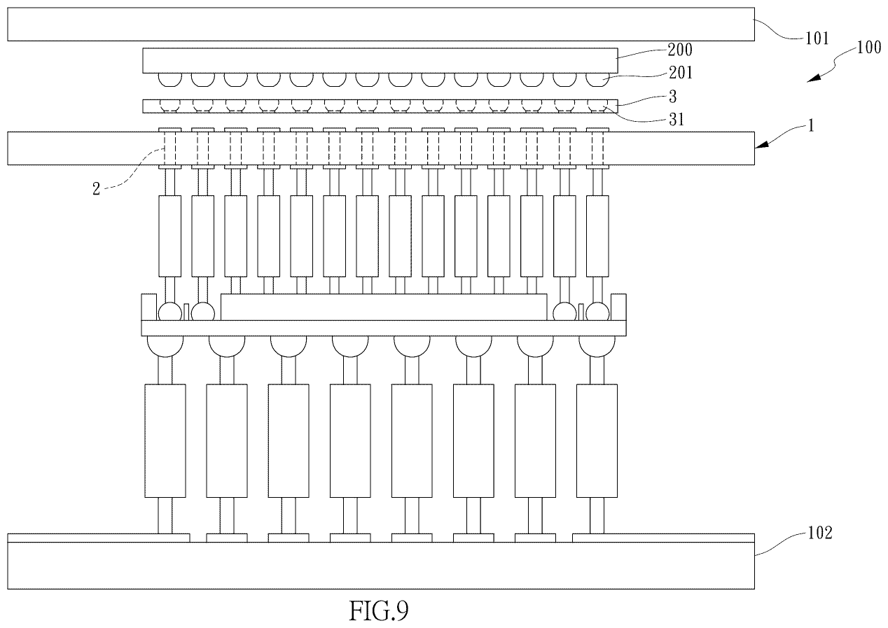

In addition to the designs of the recessed concave portion 14 of the interposer 1 described above, a supporting board 3 can be stacked on the interposer 1 with no recessed concave portion 14. As shown in FIGS. 9 to 12, the supporting board 3 has a plurality of through-holes 31 that penetrate from the upper surface to the lower surface. During testing, as the upper mold 101 and the lower mold 102 approach each other, the interposer 1 gradually approaches the test probes 300 to allow the conductive elements 2 to electrically contact the test probes 300. And, the electronic circuit device 200 gradually approaches and abuts against the supporting board 3, with the plurality of solder balls 201 corresponding to and inserting into the through-holes 31 of the supporting board 3. After entering the through-holes 31, the solder balls 201 can make partial electrical contact with the conductive elements 2. The portions of the electronic circuit device 200 without the solder balls 201 abut against the upper surface of the supporting board 3, preventing the solder balls 201 from being directly pressed and cracking. The supporting board 3 is made of a flexible material, which can be an insulating rubber material. Thus, it can be seen that the arrangement of the supporting board 3 in the third embodiment of the present invention is utilized to distribute the force on the solder balls 201, protecting the solder balls 201 from cracking.

What is claimed is:

1. A test interposer modular structure applied in a test packaging machine, which includes an upper mold and a lower mold,
wherein an interposer is located between the upper mold and the lower mold and includes an upper top surface, a lower bottom surface and four side surfaces, and the upper top surface is recessed toward the lower bottom surface to form a concave portion with a blocking portion on a periphery of the concave portion;
wherein when conducting a test, as the upper mold and the lower mold approach each other, a plurality of solder balls of an electronic circuit device located between the interposer and the upper mold enter the concave portion, while portions of the electronic circuit device without the plurality of solder balls abut against the blocking portion to prevents direct pressure on the solder balls, avoiding cracks.

2. The test interposer modular structure as claimed in claim 1, wherein the concave portion is formed as a groove recessed from the upper top surface towards the lower bottom surface; a plurality of conductive elements are embedded between the concave portion and the lower bottom surface; the test packaging machine further includes a plurality of test probes; during testing operations, as the upper mold and lower mold come together, the interposer gradually approaches the test probes, enabling the conductive elements to make electrical contact with the test probes; and the electronic circuit device gradually approaches the interposer, such that the solder balls enter the concave portion to make electrical contact with the conductive elements, while the portions of the electronic circuit device without the plurality of solder balls abut against the blocking portion of the interposer.

3. The test interposer modular structure as claimed in claim 2, wherein an interior of the groove of the concave portion further includes a plurality of partitions arranged in a grid pattern to form a plurality of compartments corresponding to positions of the solder balls.

4. The test interposer modular structure as claimed in claim 1, wherein the concave portion of the interposer is further formed with a supporting portion at a central position thereof, and the supporting portion and the blocking portion collectively support the electronic circuit device.

5. A test interposer modular structure applied in a test packaging machine, which includes an upper mold and a lower mold,
wherein an interposer is located between the upper mold and the lower mold and a supporting board is stacked on the interposer, and the supporting board has a plurality of through-holes extending from an upper surface to a lower surface;
wherein when conducting a test, as the upper mold and the lower mold approach each other, a plurality of solder balls of an electronic circuit device located between the supporting board and the upper mold enter the corresponding through-holes, while portions of the electronic circuit device without the plurality of solder balls abut against the upper surface of the supporting board to prevents direct pressure on the solder balls, avoiding cracks.

6. The test interposer modular structure as claimed in claim 5, wherein the supporting board is made of flexible material, which is an insulating rubber material.

7. The test interposer modular structure as claimed in claim 5, wherein a plurality of conductive elements are embedded in the interposer and correspond to the through-holes of the supporting board; the test packaging machine further includes a plurality of test probes; during testing operations, as the upper mold and lower mold come together, the interposer gradually approaches the test probes, enabling the conductive elements to make electrical contact with the test probes; and the electronic circuit device gradually approaches and abuts against the supporting board, while the plurality of solder balls of the electronic circuit device correspond to and enter the through-holes of the supporting board, allowing the solder balls within the through-holes to make partial electrical contact with the conductive elements.
